(19) United States
(12) Patent Application Publication
(10) Pub. No.: US 2013/0237402 A1
(43) Pub. Date: Sep. 12, 2013

(54) SAPPHIRE MATERIAL AND PRODUCTION METHOD THEREOF

(71) Applicants: Wei-Hsiang Wang, Hsinchu (TW); Chen-Hui Wu, Hsinchu (TW); Chuan-Lang Lu, Hsinchu (TW)

(72) Inventors: Wei-Hsiang Wang, Hsinchu (TW); Chen-Hui Wu, Hsinchu (TW); Chuan-Lang Lu, Hsinchu (TW)

(73) Assignee: TERA XTAL TECHNOLOGY CORPORATION

(21) Appl. No.: 13/486,794

(22) Filed: Jun. 1, 2012

(30) Foreign Application Priority Data
Mar. 6, 2012 (TW) 101107556

(51) Int. Cl. C30B 29/20; C30B 11/02; C01F 7/02; B28D 5/04; B24B 1/00; B28D 5/02; C30B 15/00; C30B 15/10

(52) U.S. Cl. 501/86; 117/13; 117/83; 125/12; 451/41; 408/1 R; 423/625

(57) ABSTRACT

The present invention provides a method for manufacturing a corundum substance, comprising steps of providing a corundum crystal having an a-axis and a growth along the a-axis; and obtaining the corundum substance from the corundum crystal in a particular direction.

The application claims the benefit of Taiwan Patent Application No. 101107556, filed on Mar. 6, 2012, in the Taiwan Intellectual Property Office, the disclosures of which are incorporated herein in their entirety by reference.

### FIELD OF THE INVENTION

The present invention relates to a sapphire substance and the manufacturing method thereof, particularly to a sapphire substance obtained from a sapphire crystal growing along its a-axis and the manufacturing method thereof.

### BACKGROUND OF THE INVENTION

Recently, the demand for the components used in smart phones is increased due to the increased circulation of the smart phones. These components include protecting lens used for the cameras and the cover glasses used for the touch panels of the mobile phones, and most of them have a major material of glass. Although the glass materials have the advantages such as the fine appearance, simple processing procedures, low cost, and so on, the defects of unfavorable mechanical properties including the hardness and the compressive strength cause problems in the practical applications. The techniques such as hard coating and chemical toughening/tempering could be used to improve the above defects, but result in other problems such as the additional processing cost and environmental problems.

Corundum is a crystalline form of the aluminium oxide (Al₂O₃). Pure corundum is in fact clear, and blue Corundum, or sapphire, is made up of corundum (Al₂O₃), and iron and titanium impurities (Fe²⁺ and Ti⁴⁺), which are responsible for the blue coloration. Red corundum, or ruby, is made up of corundum (Al₂O₃), and chromium impurities (Cr³⁺), which are responsible for the red coloration. Sapphire is a crystal with trigonal symmetry; its 3-fold axis, also referred to as the optical axis, is usually designated as c-axis. The a- and m-axis are both perpendicular to the c-axis. The rhombohedral cleavage plane, designated as R, is inclined at 57.6° from the c-axis in the direction of the m-axis. The sapphire single crystals are widely used as an industrial material because of its excellent mechanical characteristics, chemical stability, and optical properties, and in particular, are used for a GaN film-forming substrate for manufacturing a blue/white light emitting diode (LED).

Table 1 shows the comparisons of physical properties and optical characteristics among sapphires with various orientations and the tempered glass. In this Table, “Sapphire C-axis”, “Sapphire A-axis”, “Sapphire R-axis” and “Sapphire M-axis” indicate sapphire substances obtained from a sapphire crystal in a c-axis direction, an a-axis direction, an r-axis direction and an m-axis direction, respectively.

TABLE 1

| | | Sapphire | Sapphire | Sapphire | Sapphire | Tempered |
|---|---|---|---|---|---|---|
| | Unit | C-axis | A-axis | R-axis | M-axis | glass |
| Vickers | Kgf/cm² | 2150 ± 50 | 1850 ± 50 | 2200 ± 50 | 1850 ± 50 | 674 |
| Hardness | | | | | | |
| Young Modulus | GPa | 460 ± 50 | 460 ± 50 | 460 ± 50 | 460 ± 50 | 71.7 |
| Compressive | MPa | ≧2000 | ≧2000 | ≧2000 | ≧2000 | ≧800 |
| strength | | | | | | |
| Thermal | W/m-k | 32 ± 5 | 32 ± 5 | 32 ± 5 | 32 ± 5 | 1.2 |
| conductivity | | | | | | |
| Transmittance | % | >85 | >85 | >85 | >85 | >90 |

In Table 1, the sapphires with various orientations show better hardness and compressive strength than the tempered glass. Further, the sapphires being treated with proper processes and membrane coatings would have the optical characteristic similar to that of the tempered glass. Therefore, the combination of favorable chemical, electrical, mechanical, optical, thermal and durability properties makes sapphire a preferred material for high performance system and component designs.

Several techniques for the production of sapphire are known including the Verneuile technique, Kyropoulos, heat exchange method and so on. The sapphire made by the Verneuile technique is fragile and small, and thus is not suitable to apply to large-size applications. In addition, the edge defined film-fed growth (EFG) techniques have been used to grow the single crystal sapphire in several planar configurations including a-plane and c-plane.

In the US patent with the Publication No. 20080075941, a method and apparatus for the production of c-plane single crystal sapphire useful in the substrate of LEDs, such as gallium nitride LEDs, is disclosed. In that patent, for forming single crystal c-plane sapphire material, the method for growing the single crystal sapphire exhibiting a c-axis orientation is disclosed. However, the single crystal sapphire growing via that method not only has the defects of long growth time and energy consuming, but also is unfavorable to the subsequent processes.

Hence, because of the defects in the prior arts, the inventors provide a sapphire substance and the manufacturing method thereof to effectively overcome the demerits existing in the prior arts.

### SUMMARY OF THE INVENTION

Compared with the method for manufacturing the sapphire growing along its c-axis, it is verified that the method for manufacturing the sapphire growing along its a-axis provided in the present application is more efficient in the production, and the manufactured sapphire with a growth axis of the a-axis has a lower dislocation density. Based on different requirements, the sapphire growing along its a-axis provided in the present application could be widely used in various applications.

In accordance with one aspect of the present invention, a pharmaceutical composition for preventing or treating a chronic heart disease, particularly a chronic heart failure, is provided.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1(a) is a diagram showing a Kyropoulos crystal growing device according to a first preferred embodiment of the present application.

FIG. 1(b) is a diagram showing the sapphire crystal formed in the present application.

FIG. 2 is a diagram showing the method for manufacturing the sapphire substance according to the first preferred embodiment.

FIG. 3 is a diagram showing a heat exchange device according to a second preferred embodiment of the present application.

FIG. 4 is a diagram showing the method for manufacturing the sapphire substance according to the second preferred embodiment.

FIG. 5(a) is a diagram showing a wire cutting machining device according to a third preferred embodiment of the present application.

FIG. 5(b) is another diagram showing the wire cutting machining device according to the third preferred embodiment of the present application.

FIG. 6(a) is a diagram showing a grinding device according to a fourth preferred embodiment of the present application.

FIG. 6(b) is a diagram showing another grinding device according to the fourth preferred embodiment of the present application.

FIG. 7 is a diagram showing a polish device according to a fifth preferred embodiment of the present application.

FIG. 8 is a diagram showing manners for shaping the polished sapphire substrate according to a sixth preferred embodiment of the present application.

FIG. 9 is a diagram showing a process of shaping the polished sapphire substrate according to a seventh preferred embodiment of the present application.

FIG. 10 is a diagram showing the procedure of manufacturing and processing the sapphire substrate of the present application.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

The sapphire substance (or the sapphire material or the sapphire crystal), the manufacturing method thereof and the processing manners thereof are described in the following embodiments. The abovementioned manufacturing method and processing manners could be applied to other corundum materials, such as the ruby. The applications of the sapphire substance have been disclosed in Taiwan Patent Application No. 100142110 and Taiwan Patent Application No. 100149015, which are incorporated herein by reference.

It is noted that, as used in the specification and the appended claims, the singular forms “a,” “an” and “the” include plural referents unless the context clearly dictates otherwise.

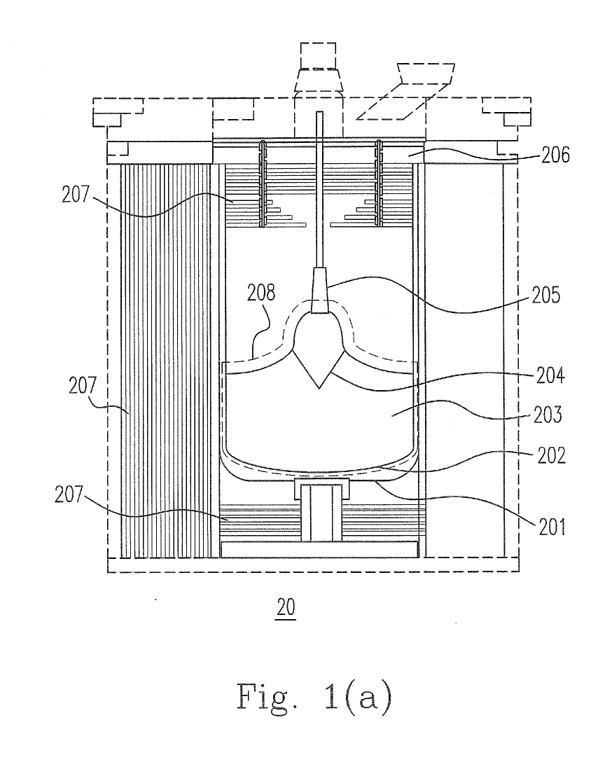

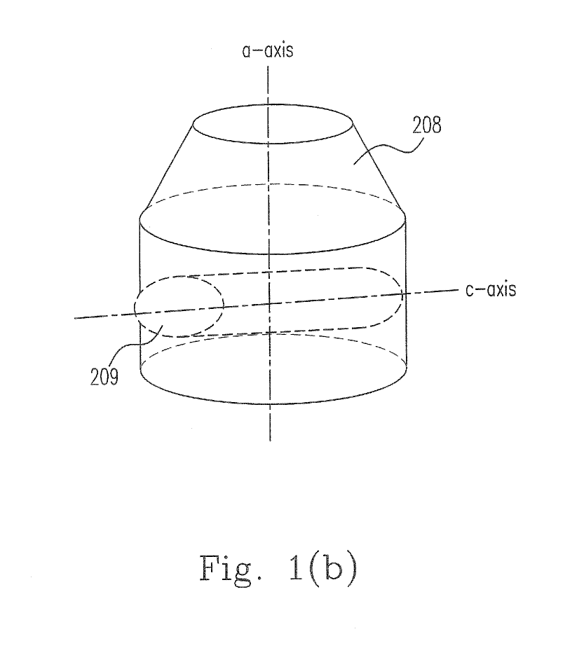

Please refer to FIG. 1(a), which is a diagram showing a Kyropoulos crystal growing device 20 according to a first preferred embodiment of the present application. The Kyropoulos crystal growing device 20 includes a resistance heater 201, a container such as a crucible 202, copper coils 206 with current running through and heat shields 207. The resistance heater 201 is made of a material including tungsten or tungsten alloys and is coupled to the copper coils 206. When an electrical current is applied to the copper coils 206, the resistance heater 201 generates heat and provides the generated heat to the crucible 202. The sapphire material, which is the high-purity Al₂O₃, is melted down to a liquid state in the crucible 202 via the resistive heating, and forms a melt 203, i.e. the molten Al₂O₃. The crucible 202 may be made of any material capable of containing the melt 203. Suitable materials for the construction of the crucible 202 include, for example, at least one of iridium, molybdenum, tungsten, molybdenum/tungsten alloys and graphite. A sapphire seed 205 is placed in a proper position in the Kyropoulos crystal growing device 20 for generating a sapphire crystal growing along its a-axis. The Kyropoulos crystal growing device 20 causes the formation of a solid-liquid interface substance 204 between the sapphire seed 205 and the melt 203. The heat shields 207 are made of a material including at least one of molybdenum and tungsten, which can help to reduce the heat loss from the crucible 202 for maintaining the temperature inside of the crucible 202.

According to the first preferred embodiment of the present invention, the method for manufacturing the sapphire substance is described as follows. Firstly, the sapphire material, which is the high-purity Al₂O₃, is placed in the crucible 202, and the sapphire seed 205 is positioned to contact with the sapphire material for generating a crystal growing in a direction of its a-axis. In FIG. 1(a), the a-axis of the sapphire seed 205 is parallel to the pulling direction, i.e. the vertical direction. The sapphire material is then melted down in the crucible 202 via the resistive heating to form the melt 203, i.e. the molten Al₂O₃, or form the melt 203 and the solid-liquid interface substance 204. The melt 203 is gradually cooled by a temperature gradient caused by gradually pulling the sapphire seed 205 upwardly, and the crystallization of the melt 203 and the solid-liquid interface substance 204 onto the sapphire seed 205 is initiated about the a-axis of the sapphire seed 205. Finally, after the completion of the above crystallization, the sapphire crystal 208 is formed and removed from the crucible 202.

Please refer to FIG. 1(b), which is a diagram showing the sapphire crystal 208 formed in the present application. As shown, the sapphire crystal 208 has a growth axis parallel to the a-axis. Next, the sapphire substance 209 is obtained from the sapphire crystal 208 so as to perform the subsequent procedures, and preferably, the orientations of the sapphire crystal 208 are determined by the x-ray diffraction based on the demand prior to obtaining the sapphire substance 209. The method for obtaining the sapphire substance 209 includes the manner of drilling or cutting the sapphire crystal 208. For example, a hollow cylindrical drill coated with diamond grain around the cutting edge of drill could be used to obtain the cylindrical sapphire substance 209, and a diamond saw could be used to cut the sapphire crystal 208 for obtaining the sapphire substance 209 with a shape of a rectangular column or a polygonal column. The sapphire substance 209 is obtained in a particular direction substantially perpendicular to the a-axis. The sapphire substance 209 may be obtained from the sapphire crystal 208 in the horizontal direction, i.e. the c-axis in the example of FIG. 1(b) or the m-axis (not shown), perpendicular to the a-axis, wherein the c-axis is perpendicular to the m-axis.

In another preferred embodiment, the particular direction could be a direction tilted from the c-axis of the sapphire crystal 208 by an angle in a range of −2.5° to 2.5° toward the a- and m-axis. The sapphire substance 209 obtained in the direction defined above has a better transmittancy. When it is intended to obtain the sapphire substance 209 in a direction parallel to the c-axis completely perpendicular to the a-axis, it is not easy to drill the sapphire crystal 208 because of its structure. Accordingly, the abovementioned particular direction is preferably a direction inclined from the c-axis of the sapphire crystal 208 to the a-axis by −2.5° to 2.5°; a direction inclined from the c-axis of the sapphire crystal 208 to the m-axis by −2.5° to 2.5°; a direction inclined from the a-axis of the sapphire crystal 208 to the c-axis by an angle in a range of −2.5° to 2.5°; a direction inclined from the a-axis of the sapphire crystal 208 to the m-axis by an angle in a range of −2.5° to 2.5°; a direction inclined from the m-axis of the sapphire crystal 208 to the c-axis by an angle in a range of −2.5° to 2.5°; a direction inclined from the m-axis of the sapphire crystal 208 to the a-axis by an angle in a range of −2.5° to 2.5°; or a direction parallel to the r-axis of the sapphire crystal 208. Based on the above preferred particular directions, it is easy to perform the drilling procedure and the obtained sapphire substance 209 would have a better transmittancy. The Miller indices of the above particular directions include: the c-axis (0001), the a-axis ( 1̅ 1̅ 20;1 2̅ 10;2 1̅ 1̅ 0;11 2̅ 0; 1̅ 2 1̅ 0; 2̅ 110), the m-axis (0 1̅ 10;1 1̅ 00;10 1̅ 0;01 1̅ 0; 1̅ 100; 1̅ 010) and the r-axis (10 1̅1;1 1̅0 1̅;01 1̅ 1̅; 1̅01 1̅; 1̅101;0 1̅11).

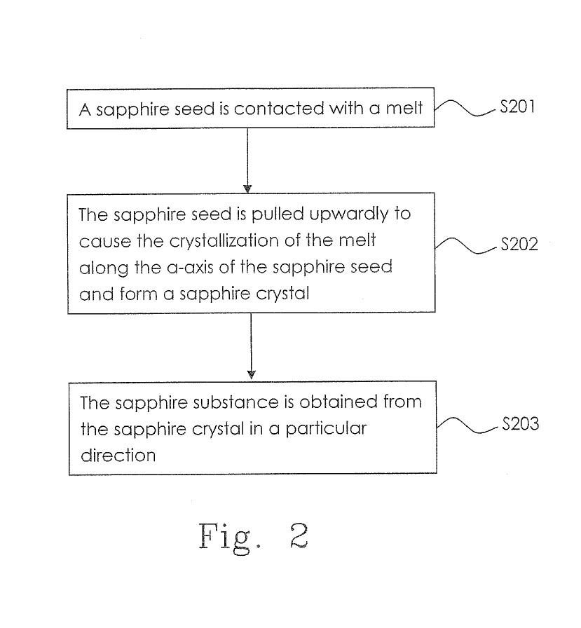

Please refer to FIG. 2, which is a diagram showing the method for manufacturing the sapphire substance 209 according to the first preferred embodiment. The method includes the following steps. In Step S201, a sapphire seed 205 is contacted with a melt 203. In Step S202, the sapphire seed 205 is pulled upwardly to cool the melt 203 gradually and cause the crystallization of the melt 203 along the a-axis of the sapphire seed 205 to form a sapphire crystal 208. In Step S203, the sapphire substance 209 is obtained from the sapphire crystal 208 in a particular direction, preferably perpendicular to the a-axis of the sapphire seed 205 or the sapphire crystal 208.

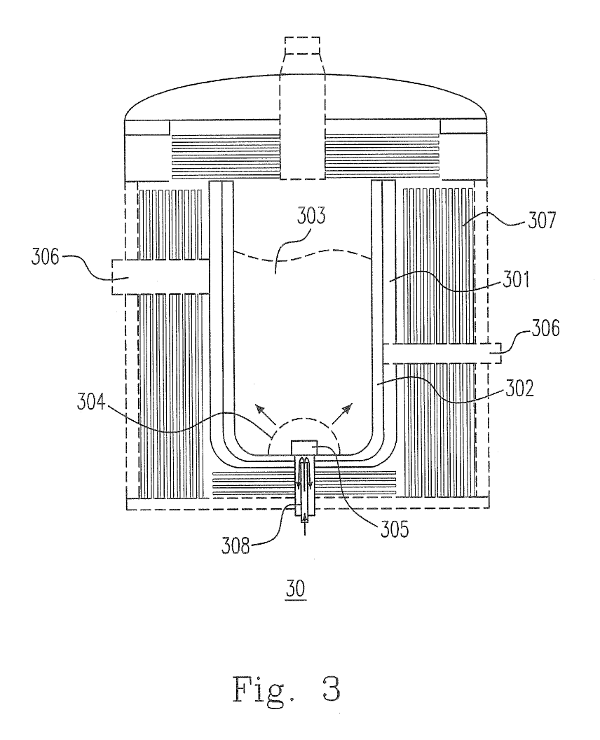

Please refer to FIG. 3, which is a diagram showing a heat exchange device 30 according to a second preferred embodiment of the present application. The heat exchange device 30 includes a resistance heater 301, a crucible 302, a sapphire seed 305, at least one current coil 306 coupled to the resistance heater 301, heat shields 307 and heat exchange pipes 308. When the current coil 306 is applied with an electrical current, the crucible 302 would be heated by an energy provided by the resistance heater 301. The melt 303 may be formed from the sapphire material, i.e. the high-purity Al₂O₃. A sapphire seed 305 is placed in a proper position in the heat exchange device 30 for generating a sapphire crystal growing in a direction parallel to its a-axis. The heat exchange device 30 causes the formation of a solid-liquid interface substance 304 between the sapphire seed 305 and the melt 303.

Based on the second preferred embodiment of the present invention, the method for manufacturing the sapphire substance is described as follows. Firstly, the sapphire material, which is the high-purity Al₂O₃, is placed in the crucible 302, and a seeding procedure is performed by contacting the sapphire seed 305 with the sapphire material. In FIG. 3, the a-axis of the sapphire seed 305 is parallel to the vertical direction. The sapphire material is then melted down in the crucible 302 via the resistive heating to form the melt 303, i.e. the molten Al₂O₃, or form the melt 303 and the solid-liquid interface substance 304. The heat in the solid-liquid interface substance 304 and the melt 303 is removed by a heat exchange manner by the cooling water or the vapor circulating in the heat exchange pipes 308 so that the solid-liquid interface substance 304 and the melt 303 is cooled gradually from the bottom to the top, and the crystallization of the melt 303 and the solid-liquid interface substance 304 onto the sapphire seed 305 is initiated about the a-axis of the sapphire seed 305. Finally, a sapphire crystal 208 having a growth axis parallel to its a-axis the same as that shown in FIG. 1(b) is formed after the termination of the above crystallization. The crucible 302 may be any shape or size that is suitable for forming the crystals with a desired shape, so as to increase the volume utilization of the crystals during the subsequent procedures. For example, the crucible 302 may be substantially rectangular, square, cylindrical or polygonal. The shape of the sapphire crystal 208 would be varied depending on the shape of the crucible 302. Next, the procedures for obtaining the sapphire substance 209 from the sapphire crystal 208 are the same as those described above and thus are not described repeatedly herein.

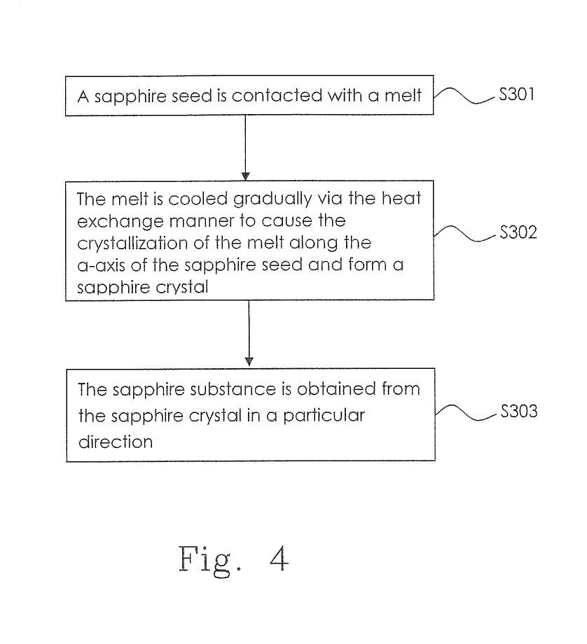

Please refer to FIG. 4, which is a diagram showing the method for manufacturing the sapphire substance 209 according to the second preferred embodiment. The method includes the following steps. In Step S301, a sapphire seed 305 is contacted with a melt 303. In Step S302, the melt 303 is cooled gradually via the heat exchange manner and cause the crystallization of the melt 303 along the a-axis of the sapphire seed 305 to form a sapphire crystal 208. In Step S303, the sapphire substance 209 is obtained from the sapphire crystal 208 in a particular direction, preferably perpendicular to the a-axis of the sapphire seed 305 or the sapphire crystal 208.

The crystal axis of the sapphire substance 209 is preferably one of the c-axis (0001), the a-axis [including (1 2̅10), (11 2̅0), (2 1̅ 1̅0), ( 1̅ 1̅20), ( 2̅110), and ( 1̅2 1̅0)], the m-axis [including ( 1̅010), ( 1̅100), (01 1̅0), (10 1̅0), (1 1̅00), and (0 1̅10)] and the r-axis [including (10 1̅1), ( 1̅01 1̅), (01 1̅ 1̅), (0 1̅11), (1 1̅0 1̅), and ( 1̅101)]. After the sapphire substance 209 is obtained from the sapphire crystal 208, it is processed by a series of operations, such as dicing, drilling, milling, grinding, edge grinding, polishing, beveling, cutting, coating, and so on.

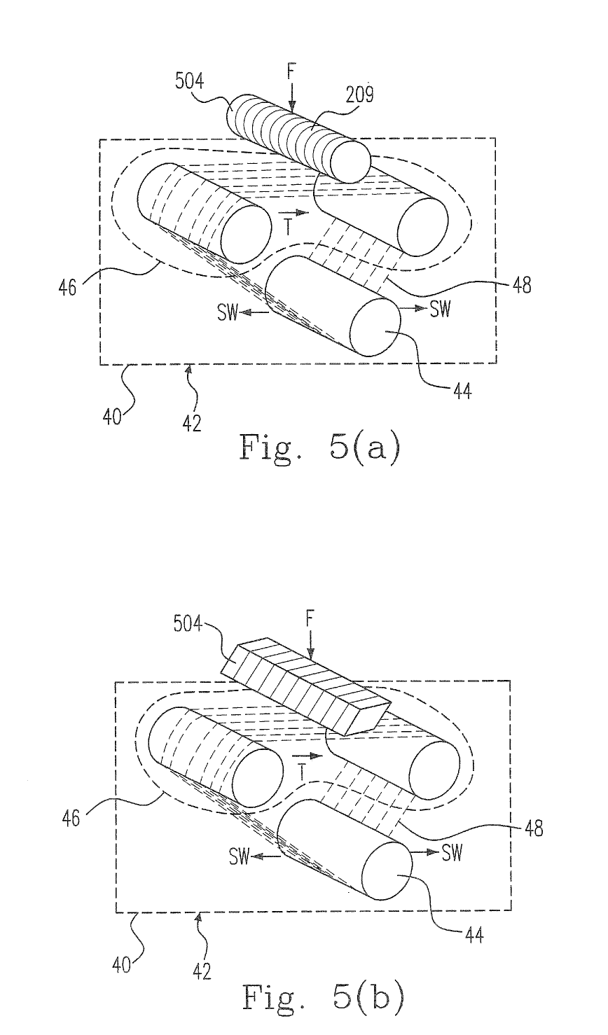

Please refer to FIGS. 5(a) and 5(b), each of which is a diagram showing a wire cutting machining device 40 according to a third preferred embodiment of the present application. The wire saw cutting machining device 40 includes a driving device 42. The driving device 42 includes a primary sheave roller 44 and a set of guide-rollers 46. A plurality of diamond wires 48 are wound around the driving device 40, and may be separated by a distance ranged between 0.65 to 1.85 mm, and thus the cutting spacing for the sapphire substance 209 may be ranged between 0.65 to 1.85 mm. When the sapphire substance 209 is to be sliced off, a force, F, is applied to the sapphire substance 209, and the driving device 42 performs a rocking motion so that the plurality of diamond wires generate a wire tension, T. Due to the wire tension, T, and the movement of the diamond wires, the sapphire substance 209 is sliced into at least one sapphire substrate 504 with a thicknesses ranged between 0.4 to 1.6 mm.

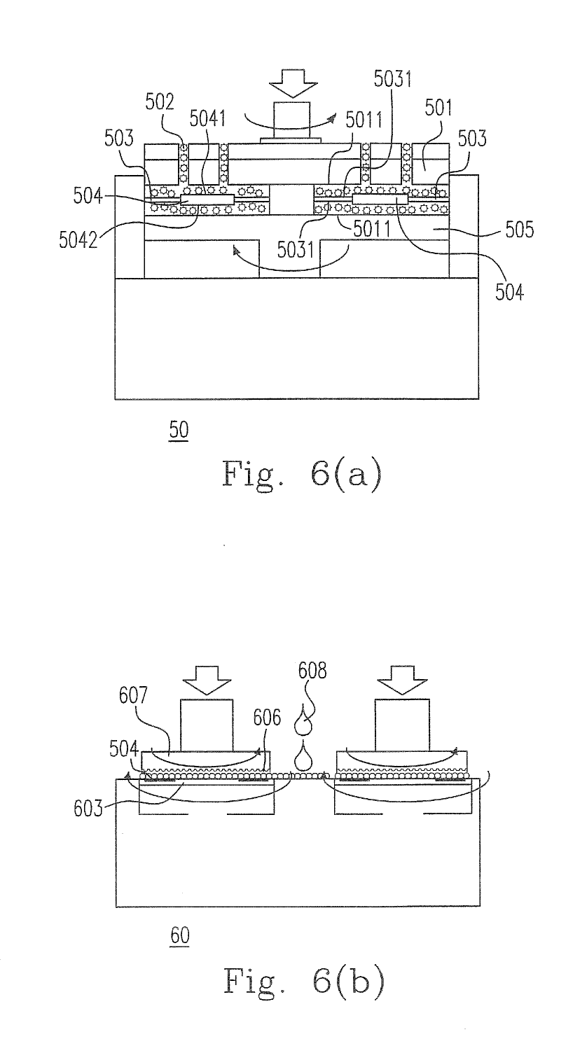

Please refer to FIG. 6(a), which a diagram showing a grinding device 50 according to a fourth preferred embodiment of the present application. The grinding device 50 includes an upper grinding disk 501, a lower grinding disk 505 and a hollow carrier disk 503. Since after the wire cutting, there might be saw marks on a first surface 5041 and a second surface 5042 of the sapphire substrate 504, the processes of grinding and thinning may be required. Firstly, the sapphire substrate 504 is placed in the hollow carrier disk 503 and fixed between the upper grinding disk 501 and the lower grinding disk 505, and the grind would be achieved via the rotations of the upper grinding disk 501 and the lower grinding disk 505. The hollow carrier disk 503 has gears 5031 configured inside and outside of the rim thereof and engaging with the inside gear 5011 of the upper grinding disk 501 and the outside gear of the lower grinding disk 505. Through the engagement of the gears, the hollow carrier disk 503 and the sapphire substrate 504 fixed therein are moved by the rotations of the upper grinding disk 501 and the lower grinding disk 505. While the hollow carrier disk 503 is moved, a grinding slurry 502 is fed into the upper grinding disk 501, and the first surface 5041 and the second surface 5042 of the sapphire substrate 504 are ground by the upper grinding disk 501 and the lower grinding disk 505, respectively. Preferably, the grinding slurry 502 comprises diamond grains.

Please refer to FIG. 6(b), which a diagram showing another grinding device 60 according to the fourth preferred embodiment of the present application. In another preferred embodiment, the grinding device 60 comprises a carrier disk 603 and an upper grinding disk 607. The grinding media such as the diamond grains 606 could be fixed on the upper grinding disk 607 by the electroforming, the resin adhesive or the like. While the sapphire substrate 504 fixed on the carrier disk 603 with wax or glue is ground, a grinding slurry 608 is used to cool and lubricate the sapphire substrate 504, the upper grinding disk 607 and the diamond grains 606.

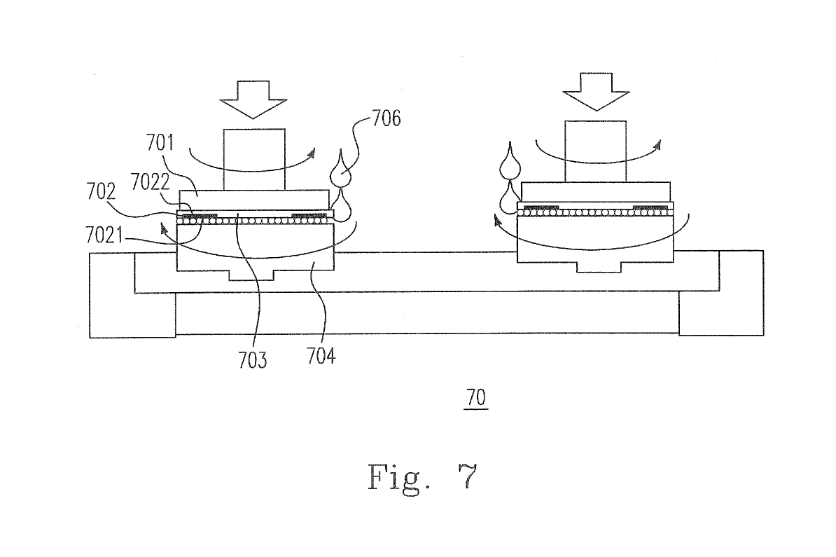

Please refer to FIG. 7, which is a diagram showing a polish device 70 according to a fifth preferred embodiment of the present application. After the grinding process, there may be still tiny scars on the surface of the ground sapphire substrate 702, and thus a polishing process is required. The polish device 70 comprises an upper polishing disk 701, a lower polishing disk 704 and a polishing carrier disk 703. Firstly, the sapphire substrate 702 that has been ground is placed on the polishing carrier disk 703, which could be a ceramic disk or a glassfiber disk. Then, the polishing carrier disk 703 is adhered or fixed to the upper polishing disk 701, and the polishing slurry (fluid) 706 is provided between the sapphire substrate 702 and the lower polishing disk 704. The upper polishing disk 701 is slowly pressed down and meanwhile the upper polishing disk 701 and the lower polishing disk 704 are rotated.

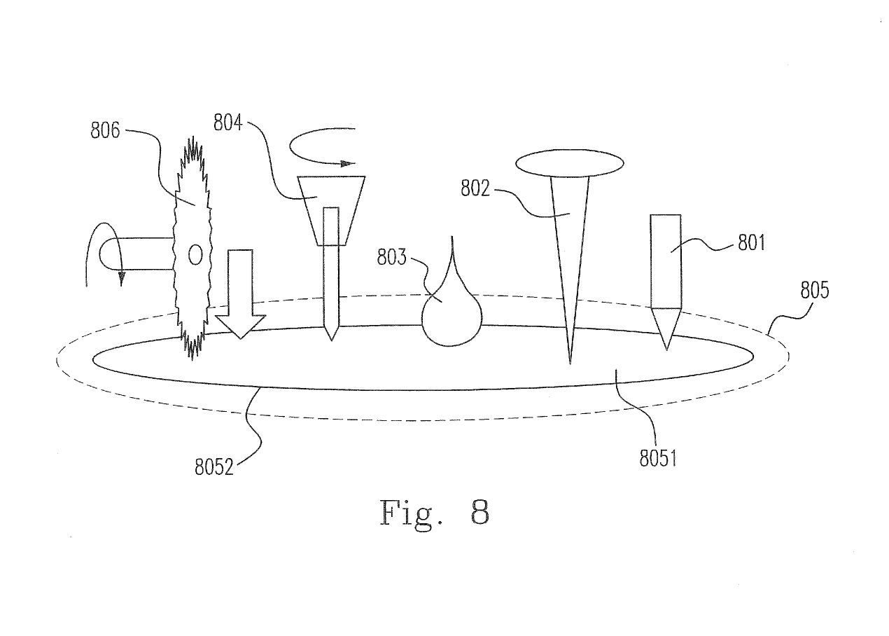

After one surface of the sapphire substrate 702 is polished, the sapphire substrate 702 is reversed to repeat the above-mentioned polishing steps for another surface thereof. The first surface 7021 and the second surface 7022 are polished by the polishing fluid 706 and form a third surface 8051 and a fourth surface 8052 (shown in FIG. 8), respectively. As shown in FIG. 8, each of the third surface 8051 and the fourth surface 8052 has a flatness and a roughness, and the polished sapphire substrate 702 has a total thickness variation (TTV) and a bow value. After the polishing process, the flatness could be controlled in a range of 0-20 micron/inch, the roughness could be controlled in a range of 0.2-10 nm, the TTV could be controlled in a range of 0-15 micron/inch, and the bow value could be controlled in a range of −30 to +30 micron.

Please refer to FIG. 8, which is a diagram showing processes for shaping the polished sapphire substrate 805 according to a sixth preferred embodiment of the present application. The sapphire substrate 805 processed by the grinding and polishing procedures could be cut into a particular shape with a mechanical process or a chemical process. The mechanical process could be achieved by cutting wheels 806, a high speed CNC machine 804, a laser system 802 or a diamond saw 801. The chemical process could be achieved by etching the sapphire substrate 805 via a chemical agent.

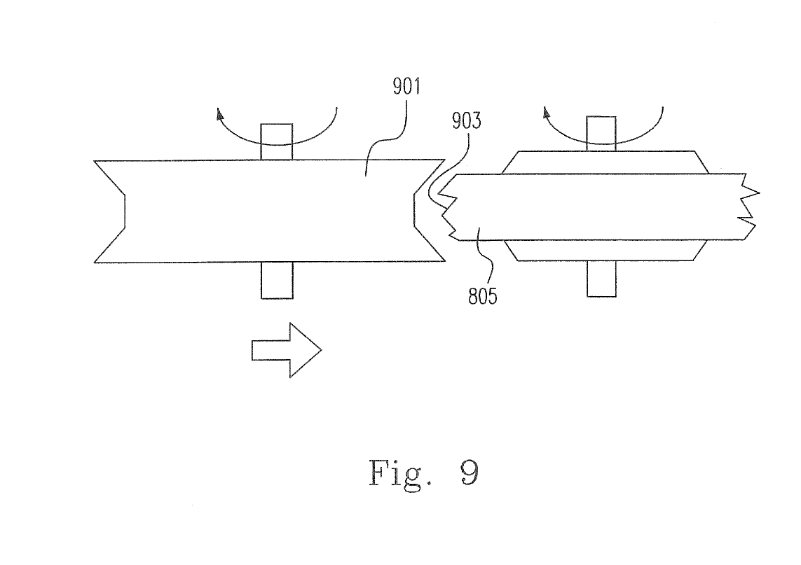

Please refer to FIG. 9, which is a diagram showing a process of shaping the polished sapphire substrate 805 according to a seventh preferred embodiment of the present application. If the shaped sapphire substrate has serrate ends, the serrate surface thereof such as the fifth surface 903 could be smoothed with an apparatus such as a diamond grinder 901. In a preferred embodiment, the diamond grinder 901 could be a T-type grinder. In another preferred embodiment, the diamond grinder 901 could be replaced with an R-type grinder, a C-Type grinder or a flat-head grinder depending on the demand for the products. In the seventh embodiment, the movement of the diamond grinder 901 is programmed by the computer numerical tracer control. Further, the fifth surface 903 of the sapphire substrate 805 could be shaped into any desired shapes via the tracer control. For example, the fifth surface 903 could be ground to have a circular, square, polygonal or irregular shape, or have a chamfer or round angle within a desired angle range. Subsequently, a coating or decorating process may be applied to the sapphire substrate 805.

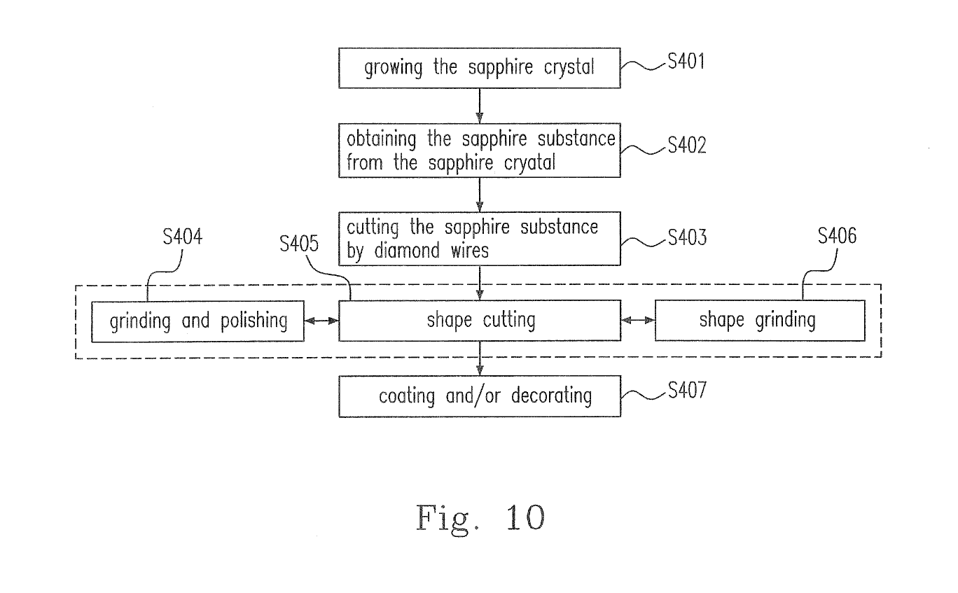

Please refer to FIG. 10, which is a diagram showing the procedure of manufacturing and processing the sapphire of the present application. The method comprises the following steps. In Step S401, the sapphire crystal 208 is growing from the cooled solid-liquid interface substances 204, 304 and the melts 203, 303, and selectively, the crystal orientation of the sapphire crystal 208 could be measured with a measuring device. In Step S402, the sapphire substance 209, which may be a cylindrical crystal rod, a rectangular brick or a polygonal brick, is obtained from the sapphire crystal 208. In Step S403, a multi-wire diamond cutting process is performed to the sapphire substance 209 so as to form the sapphire substrate 504. In Step S404, the grinding and polishing processes are performed, and then the sapphire substrate 805 is washed and checked for any holes or defects on the third surface 8051 and the fourth surface 8052 where the holes or defects may cause a decrease in the hardness or the compressive strength. After the above check, a process of stress releasing may be performed to the sapphire substrate 805, and then Steps S405 and S406 could be performed. In Step S405, a shape cutting process is performed. In Step S406, a shape grinding process is performed. In Steps S405 and Step S406, a mechanical process or a chemical process could be selected depending on the required size and shape of the final product. In Step S407, a coating or decorating process is performed on the sapphire substrate 805. Finally, an annealing treatment to the surface of the sapphire substrate 805 is selectively performed based on the surface condition. The optical properties such as the transmittance may be determined so as to confirm that the sapphire substrate 805 with the optical properties complying with the requirements could be applied to various devices.

Both the first preferred embodiment and the second preferred embodiment of the present application include Steps S401 and S402, the difference there between is that different devices and methods are used to manufacture the sapphire substance 209. Step S403 shown in FIG. 10 is also included in the third preferred embodiment of the present application. Step S404 shown in FIG. 10 is also included in the fourth and fifth preferred embodiments of the present application. Step S405 and Step S406 shown in FIG. 10 are included in the sixth and seventh preferred embodiments, respectively. It is noted that Steps S401-S407 could be performed in order. However, the double-headed arrows among Steps S404, S405 and S406 indicate these steps could be performed in any order due to the good physical properties, e.g. the high hardness, of the sapphire. Further, one skilled in the art could selectively perform at least one of Steps S404, S405 and S406 according to the actual demands. For example, after the multi-wire diamond cutting process in Step S403, the sapphire substance could merely be processed by the shape grinding in Step 406 prior to entering Step S407.

After the completion of Steps S404, S405 and/or Step S406, the sapphire substrate would have a transparent appearance and could be a sapphire glass with a transmittance equal to or greater than 85%, and a subsequent process such as the process of coating a reflective layer for improving the optical characteristics thereof could be performed.

In Step S407, the further processes for the sapphire substrate may include the functional coating and/or decorative coating. The functional coating is including but not limited to the process of coating an anti-reflective layer on the sapphire substrate for increasing the transmittance to 90% or more. The decorative coating is including but not limited to the processes of coating a metal-containing layer on the sapphire substrate for increasing the metallic luster and various printing processes, e.g. the ink transfer printing.

The sapphire glass could be applied to the touch panel or the protecting lens of a camera module. Due to the outstanding properties such as the high hardness and compressive strength, the sapphire glass could replace the tempered glass and applied to various devices.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention.

### Embodiments

1. A method for manufacturing a sapphire substance, comprising steps of:
providing a sapphire crystal having an a-axis and a growth axis parallel to the a-axis; and
obtaining the sapphire substance from the sapphire crystal in a particular direction, wherein the sapphire crystal has a c-axis, an m-axis and an r-axis, and the particular direction includes one selected from a group consisting of:
   a first direction deflected from the c-axis of the sapphire crystal toward the a-axis by an angle having a range of −2.5° to 2.5°
   and toward the m-axis by the angle having a range of −2.5° to 2.5°;
   a second direction deflected from the a-axis of the sapphire crystal toward the c-axis by the angle having a range of −2.5° to 2.5°
   and toward the m-axis by the angle having a range of −2.5° to 2.5°;
   a third direction deflected from the m-axis of the sapphire crystal toward the c-axis by the angle having a range of −2.5° to 2.5°
   and toward the a-axis by the angle; and
   a fourth direction is the r-axis of the sapphire crystal.

2. A method for manufacturing a corundum substance, comprising steps of:
providing a corundum crystal seed having an a-axis;
growing a corundum crystal boule along the a-axis from the corudum seed; and
obtaining the corundum substance from the corundum crystal in a particular direction.

3. The method of the embodiment 2, wherein the corundum crystal is a sapphire crystal having the a-axis, and the corundum substance is a sapphire substance, and the step of providing the sapphire crystal includes sub-steps of:
melting a sapphire material into a melt;
contacting a sapphire seed with the melt; and
initiating a crystallization of the melt onto the sapphire seed to form the sapphire crystal growing along the a-axis.

4. The method of any of the preceding embodiments, wherein the sapphire material is melted in a crucible.

5. The method of any of the preceding embodiments, wherein the crucible has a shape being one selected from a group consisting of a cylindrical shape, a rectangular shape and a polygonal shape.

6. The method of any of the preceding embodiments, wherein the step of initiating the crystallization of the melt includes a sub-step of:
pulling the sapphire seed upwardly for generating a temperature gradient.

7. The method of any of the preceding embodiments, wherein the melt includes a molten Al₂O₃.

8. The method of any of the preceding embodiments, wherein the sapphire crystal has a c-axis, an m-axis and an r-axis, and the particular direction includes one selected from a group consisting of:
a first direction deflected from the c-axis of the sapphire crystal toward the a-axis by an angle having a range of −2.5° to 2.5°
and toward the m-axis by the angle having a range of −2.5° to 2.5°;
a second direction deflected from the a-axis of the sapphire crystal toward the c-axis by the angle having a range of −2.5° to 2.5°
and toward the m-axis by the angle having a range of −2.5° to 2.5°;
a third direction deflected from the m-axis of the sapphire crystal toward the c-axis by the angle having a range of −2.5° to 2.5°
and toward the a-axis by the angle having a range of −2.5° to 2.5°; and
a fourth direction parallel to the r-axis of the sapphire crystal.

9. The method of any of the preceding embodiments, wherein the particular direction has a Miller index being one selected from a group consisting of a c-axis (0001); an a-axis ( 1̅ 1̅ 20;1 2̅ 10;2 1̅ 1̅ 0;11 2̅ 0; 1̅ 2 1̅ 0; 2̅ 110), the m-axis (0 1̅ 10;1 1̅ 00;10 1̅ 0;01 1̅ 0; 1̅ 100; 1̅ 010) and the r-axis (10 1̅1;1 1̅0 1̅;01 1̅ 1̅; 1̅01 1̅; 1̅101;0 1̅11).

10. The method of any of the preceding embodiments, wherein the corundum substance is obtained by at least one of a drilling manner and a cutting manner.

11. The method of any of the preceding embodiments, further comprising a step of:
slicing the sapphire substance into a sapphire substrate having a thicknesses ranged between 0.4 and 1.6 mm.

12. The method of any of the preceding embodiments, further comprising a step of:
slicing the sapphire substance into a plurality of sapphire substrates by a plurality of diamond wires separated by a distance ranged between 0.65 and 1.85 mm.

13. The method of any of the preceding embodiments, wherein the sapphire substrate has a first surface and a second surface, and the method further comprises at least a process being one selected from a group consisting of:
grinding at least one of the first surface and the second surface with a grinding media;
polishing at least one of the first surface and the second surface with a polishing slurry;
cutting the sapphire substrate by at least one of a mechanical process and a chemical process;
coating a membrane on the sapphire substrate; and
performing an ink transfer printing on the sapphire substrate.

14. The method of any of the preceding embodiments, wherein each of the first surface and the second surface of the processed sapphire substrate has a flatness in a range of 0-20 micron/inch and a roughness in a range of 0.2-10 nm.

15. The method of any of the preceding embodiments, wherein the membrane includes one of an anti-reflective membrane and a metal-containing membrane.

16. The method of any of the preceding embodiments, wherein the processed sapphire substrate has a total thickness variation (TTV) ranged between 0 and 15 micron/inch and a bow value ranged between −30 and +30 micron.

17. The method of any of the preceding embodiments, wherein the sapphire substrate is processed to form a sapphire glass having one of transmittances equal to and greater than 85%.

18. The method of any of the preceding embodiments, wherein the sapphire substrate has a serrate end, and the method further comprises a step of processing the sapphire substrate by grinding the serrate end to form one of a chamfer and a round angle.

19. A corundum substance obtained from a corundum crystal in a particular direction, wherein the corundum crystal has an a-axis, a c-axis, an m-axis, an r-axis and a growth axis parallel to the a-axis, and the particular direction includes one selected from a group consisting of:
a first direction deflected from the c-axis of the corundum crystal toward the a-axis by an angle having a range of −2.5° to 2.5°
and toward the m-axis by the angle having a range of −2.5° to 2.5°;
a second direction deflected from the a-axis of the corundum crystal toward the c-axis by the angle having a range of −2.5° to 2.5°
and toward the m-axis by the angle;
a third direction deflected from the m-axis of the corundum crystal toward the c-axis by the angle having a range of −2.5° to 2.5°
and toward the a-axis by the angle; and or
a fourth direction parallel to the r-axis of the corundum crystal.

20. The corundum substance of the embodiment 19, wherein the corundum crystal is one of a sapphire crystal and a ruby crystal.

While the invention has been described in terms of what is presently considered to be the most practical and preferred embodiments, it is to be understood that the invention needs not be limited to the disclose embodiments. Therefore, it is intended to cover various modifications and similar arrangements included within the spirit and scope of the appended claims, which are to be accorded with the broadest interpretation so as to encompass all such modifications and similar structures.

What is claimed is:

1. A method for manufacturing a sapphire substance, comprising steps of:
providing a sapphire crystal having an a-axis and a growth axis parallel to the a-axis; and
obtaining the sapphire substance from the sapphire crystal in a particular direction, wherein the sapphire crystal has a c-axis, an a-axis, an m-axis and an r-axis, and the particular direction includes one selected from a group consisting of:
a first direction deflected from the c-axis of the sapphire crystal toward the a-axis by an angle having a range of 2.5° to 2.5° and toward the m-axis by the angle having a range of −2.5° to 2.5°;
a second direction deflected from the a-axis of the sapphire crystal toward the c-axis by the angle having a range of −2.5° to 2.5°
and toward the m-axis by the angle having a range of −2.5° to 2.5°;
a third direction deflected from the m-axis of the sapphire crystal toward the c-axis by the angle having a range of −2.5° to 2.5°
and toward the a-axis by the angle having a range of −2.5° to 2.5°; and
a fourth direction parallel to the r-axis of the sapphire crystal.

2. A method for manufacturing a corundum substance, comprising steps of:
providing a corundum crystal seed having an a-axis;
growing a corundum crystal boule along the a-axis from the corudum seed; and
obtaining the corundum substance from the corundum crystal in a particular direction.

3. The method as claimed in claim 2, wherein the corundum crystal is a sapphire crystal having the a-axis, and the corundum substance is a sapphire substance, and the step of providing the sapphire crystal includes sub-steps of:
melting a sapphire material into a melt;
contacting a sapphire seed with the melt; and
initiating a crystallization of the melt onto the sapphire seed to form the sapphire crystal growing along the a-axis.

4. The method as claimed in claim 3, wherein the sapphire material is melted in a crucible.

5. The method as claimed in claim 4, wherein the crucible has a shape being one selected from a group consisting of a cylindrical shape, a rectangular shape and a polygonal shape.

6. The method as claimed in claim 3, wherein the step of initiating the crystallization of the melt includes a sub-step of:
pulling the sapphire seed upwardly for generating a temperature gradient.

7. The method as claimed in claim 3, wherein the melt includes a molten Al₂O₃.

8. The method as claimed in claim 3, wherein the sapphire crystal has a c-axis, an a-axis, an m-axis and an r-axis, and the particular direction includes one selected from a group consisting of:
a first direction deflected from the c-axis of the sapphire crystal toward the a-axis by an angle having a range of −2.5° to 2.5°
and toward the m-axis by the angle having a range of −2.5° to 2.5°;
a second direction deflected from the a-axis of the sapphire crystal toward the c-axis by the angle having a range of −2.5° to 2.5°
and toward the m-axis by the angle having a range of −2.5° to 2.5°;
a third direction deflected from the m-axis of the sapphire crystal toward the c-axis by the angle having a range of −2.5° to 2.5°
and toward the a-axis by the angle having a range of −2.5° to 2.5°; and
a fourth direction parallel to the r-axis of the sapphire crystal.

9. The method as claimed in claim 3, wherein the particular direction has a Miller index being one selected from a group consisting of a c-axis (0001); an a-axis ( 1̅ 1̅20;1 2̅10;2 1̅ 1̅0;11 2̅0; 1̅2 1̅0; 2̅110), the m-axis (0 1̅ 10;1 1̅ 00;10 1̅ 0;01 1̅ 0; 1̅ 100; 1̅ 010) and the r-axis (10 1̅1;1 1̅0 1̅;01 1̅ 1̅; 1̅01 1̅; 1̅101;0 1̅11).

10. The method as claimed in claim 2, wherein the corundum substance is obtained by at least one of a drilling manner and a cutting manner.

11. The method as claimed in claim 3, further comprising a step of:
slicing the sapphire substance into a sapphire substrate having a thicknesses ranged between 0.4 and 1.6 mm.

12. The method as claimed in claim 3, further comprising a step of:
slicing the sapphire substance into a plurality of sapphire substrates by a plurality of diamond wires separated by a distance ranged between 0.65 and 1.85 mm.

13. The method as claimed in claim 11, wherein the sapphire substrate has a first surface and a second surface, and the method further comprises at least a process being one selected from a group consisting of:
grinding at least one of the first surface and the second surface with a grinding media;
polishing at least one of the first surface and the second surface with a polishing slurry;
cutting the sapphire substrate by at least one of a mechanical process and a chemical process;
coating a membrane on the sapphire substrate; and
performing an ink transfer printing on the sapphire substrate.

14. The method as claimed in claim 13, wherein each of the first surface and the second surface of the processed sapphire substrate has a flatness in a range of 0-20 micron/inch and a roughness in a range of 0.2-10 nm.

15. The method as claimed in claim 13, wherein the membrane includes one of an anti-reflective membrane and a metal-containing membrane.

16. The method as claimed in claim 13, wherein the processed sapphire substrate has a total thickness variation (TTV) ranged between 0 and 15 micron/inch and a bow value ranged between −30 and +30 micron.

17. The method as claimed in claim 13, wherein the sapphire substrate is processed to form a sapphire glass having one of transmittances equal to and greater than 85%.

18. The method as claimed in claim 11, wherein the sapphire substrate has a serrate end, and the method further comprises a step of processing the sapphire substrate by grinding the serrate end to form one of a chamfer and a round angle.

19. A corundum substance obtained from a corundum crystal in a particular direction, wherein the corundum crystal has an a-axis, a c-axis, an m-axis, an r-axis and a growth axis parallel to the a-axis, and the particular direction includes one selected from a group consisting of:
a first direction deflected from the c-axis of the corundum crystal toward the a-axis by an angle having a range of −2.5° to 2.5° and toward the m-axis by the angle having a range of −2.5° to 2.5°;
a second direction deflected from the a-axis of the corundum crystal toward the c-axis by the angle having a range of −2.5° to 2.5° and toward the m-axis by the angle having a range of −2.5° to 2.5°;
a third direction deflected from the m-axis of the corundum crystal toward the c-axis by the angle having a range of −2.5° to 2.5° and toward the a-axis by the angle having a range of −2.5° to 2.5°; and
a fourth direction parallel to the r-axis of the corundum crystal.

20. The corundum substance as claimed in claim 19, wherein the corundum crystal is one of a sapphire crystal and a ruby crystal.
